(19) United States
(12) Patent Application Publication
(10) Pub. No.: US 2007/0042120 A1
(43) Pub. Date: Feb. 22, 2007

(54) Method of forming semiconductor layer

(75) Inventors: Yoshihiko Moriyama, Tokyo (JP); Keiji Ikeda, Tsukuba-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA and FUJITSU LIMITED

(21) Appl. No.: 11/491,300

(22) Filed: Jul. 24, 2006

(30) Foreign Application Priority Data
Aug. 16, 2005 (JP) 2005-235990

(51) Int. Cl. C23C 16/00; B05D 3/00

(52) U.S. Cl. 427/248.1; 427/299

(57) ABSTRACT

A method of forming a semiconductor layer includes cleaning a substrate having a germanium layer formed as a surface layer, with a solution containing at least one selected from the group consisting of hydrochloric acid, hydrobromic acid, and hydroiodic acid, subjecting the substrate after the cleaning to hydrogen annealing in a CVD chamber, and introducing a deposition gas into the CVD chamber to form a semiconductor layer on the substrate.

### CROSS-REFERENCE TO RELATED APPLICATIONS

This application is based upon and claims the benefit of priority from prior Japanese Patent Application No. 2005-235990, filed Aug. 16, 2005, the entire contents of which are incorporated herein by reference.

### BACKGROUND OF THE INVENTION

1. Field of the Invention

The present invention relates to a method of forming a semiconductor layer, and more particularly to a method of forming a Ge-based/SiGe-based semiconductor layer.

2. Description of the Related Art

A metal-insulator-semiconductor type field effect transistor (MISFET) that uses Ge or SiGe for a channel layer has been proposed. To realize the MISFET, establishment of an epitaxial crystal growth technology on a Ge or SiGe substrate by a chemical vapor deposition (CVD) method is important. Securing surface flatness after the washing and cleaning is essential to the realization of epitaxial crystal growth, and a surface cleaning method of Ge or SiGe.

In Si substrate surface cleaning, some methods have mainly been employed which include cleaning with a solution containing hydrogen peroxide, e.g., a mixed solution of sulfuric acid and hydrogen peroxide prepared to decompose an organic material, cleaning with a mixed solution of hydrochloric acid and hydrogen peroxide prepared to remove metal contamination, oxide layer etching with hydrofluoric acid and water washing.

In the case of Ge, laboratory reports concerning cleaning of a Ge (100) surface have been published (e.g., “An efficient method for cleaning Ge (100) surface” by K. Prabhakarana et al., Surface Science Vol. 316, pp. L1031 to L1033, and “Carbon contamination free Ge (100) surface cleaning for MBE” by H. Okamura et al., Applied Surface Science). However, no surface cleaning process before crystal growth premised on industrial manufacturing of a semiconductor device for a Ge-based or SiGe-based substrate has been established.

When the surface of a Ge layer is processed by a solution containing hydrogen peroxide, etching progresses while oxidizing the surface, consequently causing a problem of surface roughening. Even when oxide layer etching is carried out with hydrofluoric acid, the hydrogen-terminated surface of the Ge is unstable, and therefore, contaminants are easily adsorbed. As a consequence, the cleaned surface cannot be maintained.

In the case of a microtransistor, the demand for flatness of the substrate surface is very high. A very small amount of impurities causes abnormal growth based on selective growth, leading to a problem of impaired flatness.

Therefore, there has been a desire for realization of a good surface cleaning method before crystal growth of a Ge-based or SiGe-based substrate, and a method of forming a semiconductor layer which can form a flat thin layer.

### BRIEF SUMMARY OF THE INVENTION

According to a first aspect of the invention, there is provided a method of forming a semiconductor layer which includes:

cleaning a substrate having a germanium layer formed as a surface layer, with a solution containing at least one selected from the group consisting of hydrochloric acid, hydrobromic acid, and hydroiodic acid;

subjecting the substrate after said cleaning to hydrogen annealing in a CVD chamber; and

introducing a deposition gas into the CVD chamber to form a semiconductor layer on the substrate.

According to a second aspect of the invention, there is provided a method of forming a semiconductor layer which includes:

cleaning a substrate having an SiGe layer formed as a surface layer, with a solution containing at least one selected from the group consisting of hydrochloric acid, hydrobromic acid, and hydroiodic acid;

subjecting the substrate after said cleaning to hydrogen annealing in a CVD chamber; and

introducing a deposition gas into the CVD chamber to form a semiconductor layer on the substrate.

According to a third aspect of the invention, there is provided a method of forming a semiconductor layer which includes:

cleaning a substrate having a germanium layer or a silicon germanium layer formed as a surface layer, with a solution containing at least one selected from the group consisting of hydrochloric acid, hydrobromic acid, and hydroiodic acid;

subjecting the cleaned substrate to hydrogen annealing in a CVD chamber;

introducing a monosilane or disilane gas into the CVD chamber to form a silicon layer on the substrate; and

insulating the silicon layer.

### BRIEF DESCRIPTION OF THE SEVERAL VIEWS OF THE DRAWING

FIG. 1 is a flowchart of a method of forming a semiconductor layer according to a first (or second) embodiment;

FIG. 2A is a sectional view of a substrate before a Ge layer is formed according to the first embodiment;

FIG. 2B is a sectional diagram of the substrate after the Ge layer is formed according to the first embodiment;

FIG. 3A is a sectional view of a substrate before a Ge layer is formed according to the second embodiment;

FIG. 3B is a sectional view of a substrate after a Ge layer is formed according to the second embodiment;

FIG. 4 is a photograph of a Ge layer surface taken by an atomic force microscope (AFM) in the case of cleaning with hydrogen peroxide;

FIG. 5 is a photograph of the Ge layer surface taken by the AFM in the case of cleaning with a hydrochloric acid solution;

FIG. 6 is a view showing an X-ray photoelectron spectroscopy (XPS) spectrum (Ge-2p) of a Ge substrate surface in the case of cleaning with various solutions;

FIG. 7A is a photograph of the Ge layer surface taken by the AFM in the case of cleaning with a hydrofluoric acid solution;

FIG. 7B is a photograph of a Ge layer section taken by a transmission electronic microscope (TEM) after the cleaning with the hydrofluoric acid solution;

FIG. 8A is a photograph of the Ge substrate surface taken by the AFM in the case of cleaning with a hydrochloric acid solution;

FIG. 8B is a photograph of the Ge layer section taken by the TEM after the cleaning with the hydrochloric acid solution (in the present embodiment);

FIG. 9A is an entire view of the XPS spectra (Ge-2p) of the Ge substrate surface cleaned with various solutions;

FIG. 9B is a partially enlarged view of FIG. 9A;

FIG. 10 is a flowchart of a method of forming a semiconductor layer according to a third (or fourth) embodiment;

FIG. 11A is a sectional view of a substrate before a Ge layer is formed according to the third embodiment;

FIG. 11B is a sectional view of the substrate after the Ge layer is formed according to the third embodiment;

FIG. 12A is a sectional view of a substrate before a Ge layer is formed according to the fourth embodiment;

FIG. 12B is a sectional view of the substrate after the Ge layer is formed according to the fourth embodiment;

FIG. 13A is an entire view of an XPS spectrum (Ge-3d) of an SiGe substrate surface cleaned with various solutions;

FIG. 13B is a partially enlarged view of FIG. 13A;

FIG. 14 is a view of an XPS spectra (Si-2p) of an SiGe substrate surface cleaned with various solutions;

FIG. 15 is a flowchart of a method of forming a semiconductor layer according to a fifth embodiment;

FIG. 16A is a sectional view of a substrate before an SiGe layer is formed according to the fifth embodiment;

FIG. 16B is a sectional view of the substrate after the SiGe layer is formed according to the fifth embodiment;

FIG. 17 is a flowchart of a method of forming a semiconductor layer according to a sixth embodiment;

FIG. 18A is a sectional view of a substrate before an SiGe layer is formed according to the sixth embodiment;

FIG. 18B is a sectional view of the substrate after the SiGe layer is formed according to the sixth embodiment;

FIG. 19 is a flowchart of a method of forming a semiconductor layer according to a seventh embodiment;

FIG. 20A is a sectional view of a substrate before an Si layer is formed according to the seventh embodiment;

FIG. 20B is a sectional view of the substrate after the Si layer is formed according to the seventh embodiment;

FIG. 21 is a flowchart of a method of forming a semiconductor layer according to an eighth embodiment;

FIG. 22A is a sectional view of a substrate before an Si layer is formed according to the eighth embodiment;

FIG. 22B is a sectional view of the substrate after the Si layer is formed according to the eighth embodiment;

FIG. 23 is a sectional view of a substrate showing a first method of forming a gate dielectric layer according to a ninth embodiment;

FIGS. 24A and 24B are sectional views of the substrate showing a second method of forming a gate dielectric layer according to the ninth embodiment;

FIGS. 25A to 25C are sectional views of the substrate showing a third method of forming a gate dielectric layer according to the ninth embodiment;

FIGS. 26A and 26B are sectional views of the substrate showing another method of forming a gate dielectric layer according to the ninth embodiment; and

FIGS. 27A and 27B are sectional views of a configuration of a base substrate showing yet another method of forming a gate dielectric layer according to the ninth embodiment.

### DETAILED DESCRIPTION OF THE INVENTION

According to the embodiments of the present invention described below, a surface cleaning process before formation of a semiconductor layer on a Ge layer surface is carried out with a solution containing hydrochloric acid, hydrobromic acid, or a hydroiodic acid, whereby an oxide layer and metal contaminants can be simultaneously removed while the surface of the Ge layer is maintained flat. Alternatively, a surface cleaning process before a semiconductor layer is formed on an SiGe layer surface is carried out by a solution containing hydrochloric acid, hydrobromic acid, or hydroiodic acid, whereby an oxide layer and metal contaminants can be simultaneously removed while the surface is maintained flat. The amount of residual oxygen on the surface can be further reduced as compared with that of a process by a dilute hydrofluoric acid solution. Therefore, it is quite effective as a Ge-based or SiGe-based layer surface cleaning method before epitaxial thin layer crystal growth.

The preferred embodiments of the present invention will be described below in detail with reference to the accompanying drawings.

### Fist Embodiment

The first embodiment will be described by way of example in which a Ge layer is epitaxially grown on a germanium-on-insulator (GOI) substrate. It should be noted that the GOI substrate has strong tolerance to a short channel effect because a Ge layer as an element formation layer has high carrier mobility and a GOI structure is employed, and is very promising as a substrate for manufacturing an ultra high-speed microdevice.

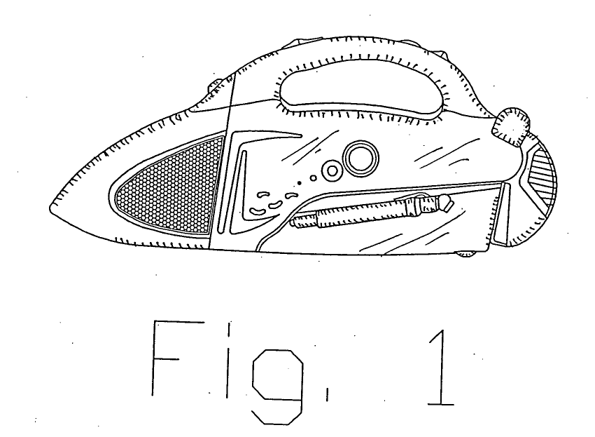

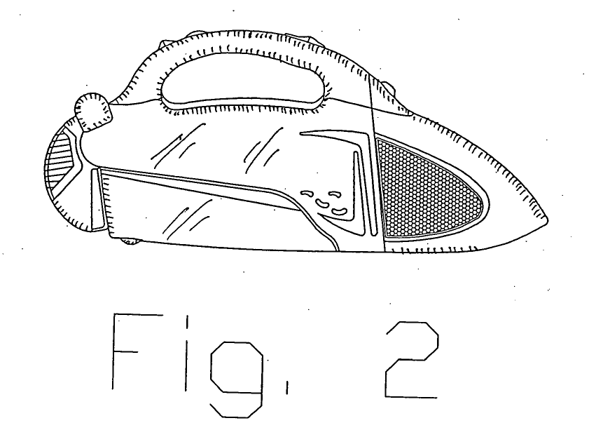

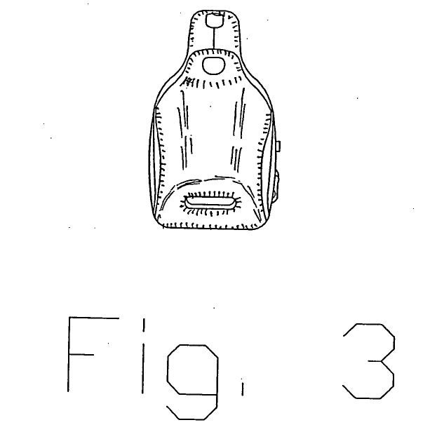

First, a GOI substrate 100 is prepared in which a GOI layer 103 having a thickness of 20 nm is formed through a silicon oxide layer (SiO₂) 102 on a silicon (Si) substrate 101 (FIG. 2A). The surface of this GOI substrate 100 is first cleaned with pure water (deionized water) by a normal method (S1 of FIG. 1), and then cleaned with a hydrochloric acid solution (S2). Hydrochloric acid in this case is generally dilute hydrochloric acid having a concentration of about 20%. However, similar effects can be obtained even when a cleaning process is carried out at about 36% near an undiluted hydrochloric acid concentration, or even when it is carried out at a more diluted hydrochloric acid concentration of about 2%. The substrate after the dilute hydrochloric acid cleaning is immediately dried (S3).

Next, the cleaned and dried substrate 100 is introduced into a CVD chamber (S4), and subjected to hydrogen annealing at 500° C. or less, e.g., 450° C., 500 Pa for 5 minutes therein (S5). Subsequently, a germane (GeH₄) gas is introduced into the CVD chamber (S6), and a Ge layer is epitaxially grown at, e.g., 400° C., 1 Pa (S7). Accordingly, as shown in FIG. 2B, a high-quality flat Ge layer 104 can be epitaxially grown as a channel layer on the GOI substrate 100.

According to the embodiment, the hydrochloric acid solution is used. However, similar effects can be obtained by using a hydrobromic acid (HBr) solution or a hydroiodic acid (HI) solution in place of the hydrochloric acid solution.

### Second Embodiment

The same effects as those of the first embodiment can be obtained even when the substrate of the first embodiment is changed from the GOI substrate 100 to a bulk Ge substrate 201. A cleaning/deposition process of the substrate is completely equivalent to that of FIG. 1 except for the substrate material, and hence, repeated explanation will be avoided.

The reason why the hydrochloric acid cleaning is effective for cleaning the Ge layer will be described below. FIG. 4 is a photograph showing an example of surface roughness when the Ge layer is cleaned with a hydrochloric acid/hydrogen peroxide solution containing hydrogen peroxide conventionally used for a silicon-based substrate cleaning method. A black spot on the surface is a pit formed by hydrogen peroxide etching. As such a pit is formed, hydrogen peroxide cannot be used for cleaning the Ge layer.

FIG. 5 shows a different photograph of the surface of the Ge layer cleaned with a hydrochloric acid solution alone without using any hydrogen peroxide. In the hydrochloric acid solution cleaning, there is no variance in surface roughness before and after cleaning, and etching causes no deterioration of the surface.

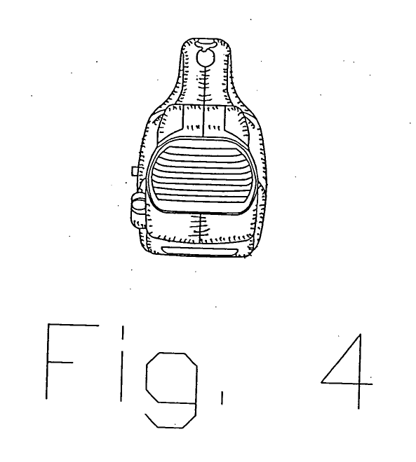

FIG. 6 shows X-ray photoelectron spectroscopy (XPS) data (Ge-2P) of the Ge substrate whose surface is cleaned with water, a hydrofluoric acid solution, and a hydrochloric acid solution. In FIG. 6, a peak around 1218 eV is a Ge peak, and a hump at 1220 eV is a Ge oxide peak. It can be understood from the drawing that the cleaning with the hydrochloric acid solution (HCl: dotted line) can reduce surface residual oxygen more than the cleaning with deionized water (DIW: solid line) or hydrofluoric acid (HF: chain line).

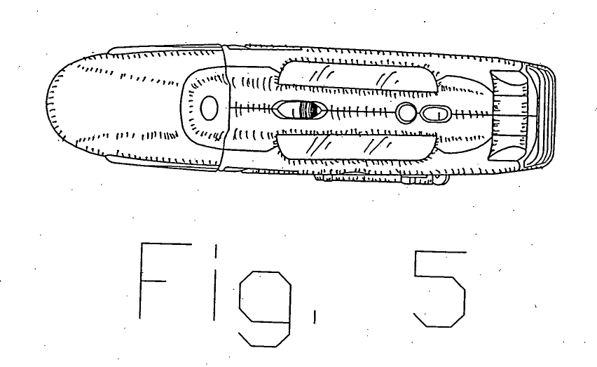

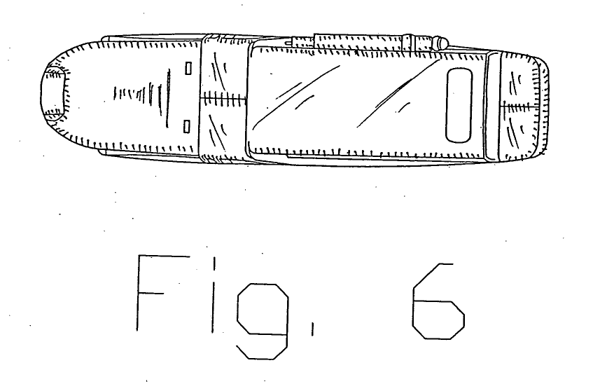

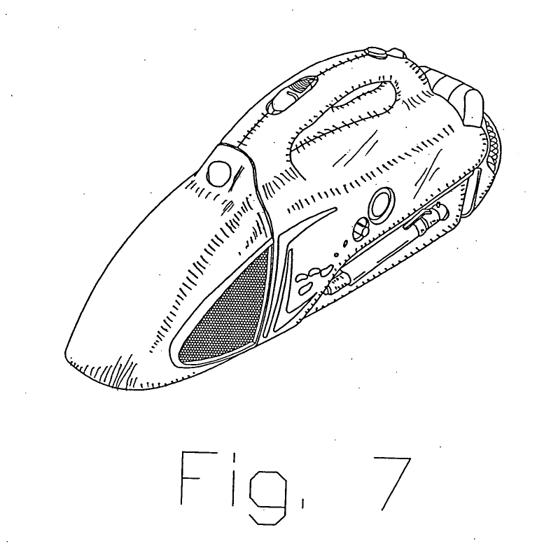

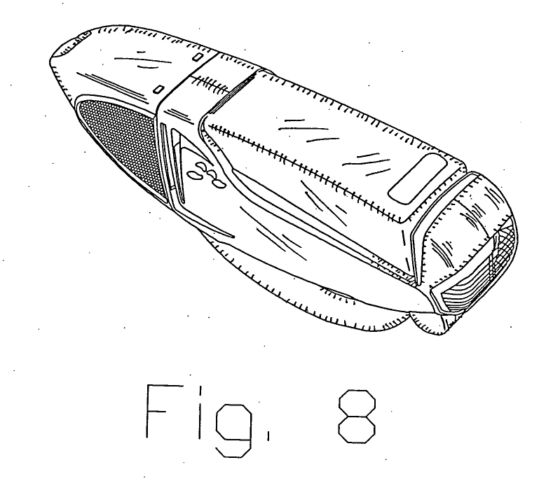

As examples, FIGS. 7A, 7B show an atomic force microscope (AFM) image and a cross-sectional transmission electron microscope (TEM) image of a sample in which a Ge channel layer is deposited on a Ge substrate cleaned with hydrofluoric acid, and FIGS. 8A, 8B show an AFM image, a cross-sectional TEM image of a sample in which a Ge channel layer is deposited on a Ge substrate cleaned with hydrochloric acid. Pits formed by etching are seen here and there in FIG. 7A, and a cross-sectional TEM image of one of them is shown in FIG. 7B. As is obvious from FIG. 7B, ruggedness occurs in a substrate surface near the pits. On the other hand, in FIGS. 8A, 8B in which the substrate is cleaned with hydrochloric acid, such pits are not formed, and an advantage of the hydrochloric acid cleaning process is shown.

Cleaning with a hydrofluoric acid-added hydrochloric acid solution is more effective in oxide layer removal than the cleaning of the Ge substrate surface by hydrochloric acid alone. FIGS. 9A, 9B show XPS data (Ge-2p) of the Ge substrate after hydrofluoric acid cleaning, hydrochloric acid cleaning, and hydrofluoric acid-added hydrochloric acid cleaning, and FIG. 9B is an enlarged view of a portion around 1225 eV of FIG. 9A. Accordingly, it can be understood that the addition of hydrofluoric acid to hydrochloric acid enables more effective removal of an oxide than the cleaning with hydrochloric acid alone.

A hydrochloric acid concentration in this case is generally 20%. However, similar effects can be obtained even when the cleaning process is carried out at about 36% near an undiluted hydrochloric acid concentration, or even when it is carried out at a more diluted hydrochloric acid concentration of about 2%. A hydrofluoric acid concentration should be set to about 1 to 3%.

### Third Embodiment

The third embodiment will be described by way of example in which a strained Ge channel layer is grown on a surface of a silicon germanium-on-insulator (SGOI) substrate.

First, an SGOI substrate 300 is prepared in which an SGOI layer 303 is formed through a silicon oxide layer 302 on a silicon substrate 301 (FIG. 11A). A surface of this SGOI substrate 300 is first cleaned with pure water by a normal method (S11 of FIG. 10), and then cleaned with a hydrofluoric acid-added hydrochloric acid solution (S12). A concentration of hydrochloric acid in this case is generally 20%. However, similar effects can be obtained even when a cleaning process is carried out at about 36% near an undiluted hydrochloric acid concentration, or even when it is carried out at a more diluted hydrochloric acid concentration of 2%. A concentration of hydrofluoric acid should be set to about 1 to 3%. The substrate after the dilute hydrochloric acid cleaning is immediately dried (S13).

Next, the cleaned and dried substrate 300 is introduced into a chemical vapor deposition (CVD) chamber (S14), and subjected to hydrogen annealing at, e.g., 800° C., 500 Pa for 20 minutes therein (S15) Subsequently, a germane (GeH₄) gas is introduced into the CVD chamber (S16), and a Ge layer is epitaxially grown at, e.g., 400° C., 1 Pa (S17). Accordingly, as shown in FIG. 11B, a high-quality flat Ge layer 304 can be epitaxially grown as a channel layer on the SGOI substrate 300.

According to the embodiment, the hydrochloric acid solution is used. However, similar effects can be obtained by using a hydrobromic acid (HBr) solution or a hydroiodic acid (HI) solution in place of the hydrochloric acid solution.

### Fourth Embodiment

The same effects as those of the third embodiment can be obtained even when the substrate of the third embodiment is changed from the SGOI substrate 300 to a bulk SiGe substrate 400 (obtained by growing an SiGe layer 402 on an Si substrate 401). A cleaning/deposition process of the substrate is completely equivalent to that of FIG. 10 except for the substrate material, and hence, repeated explanation will be avoided.

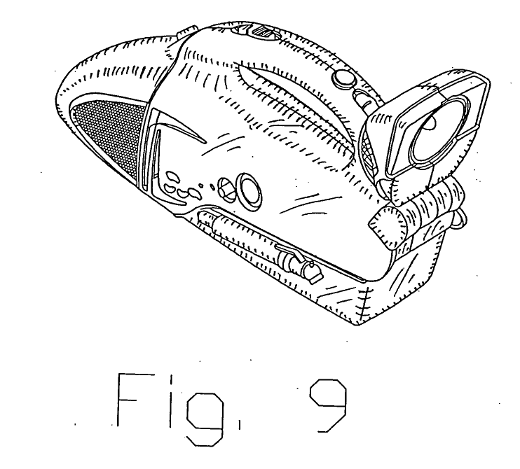

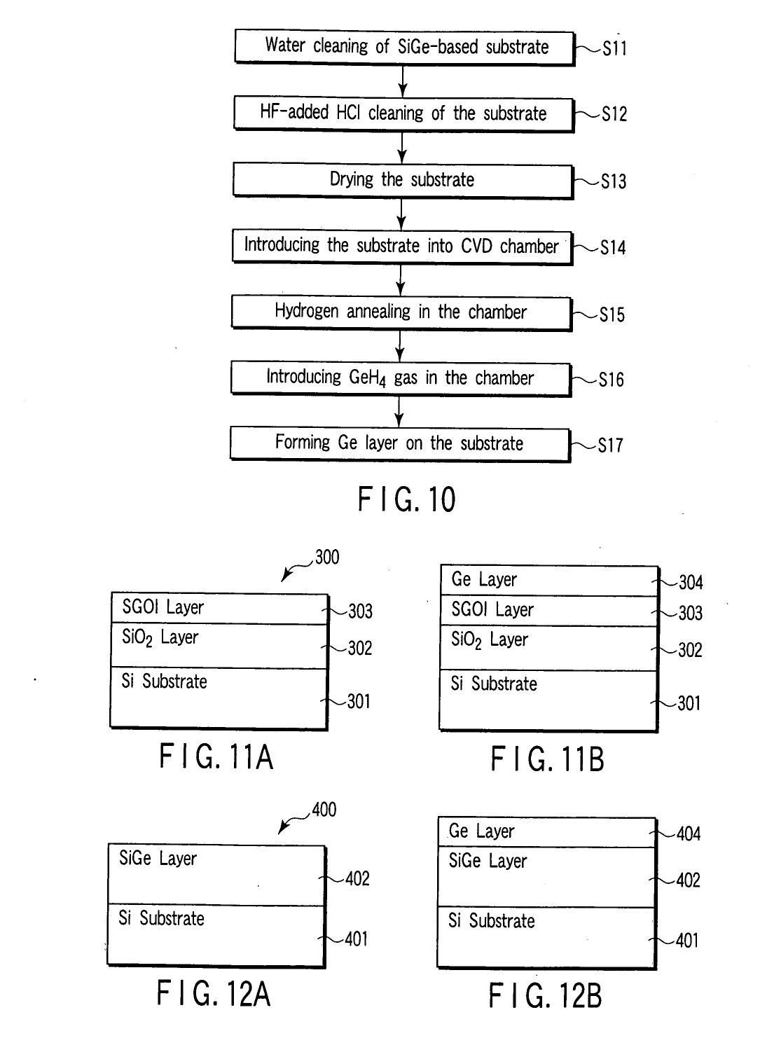

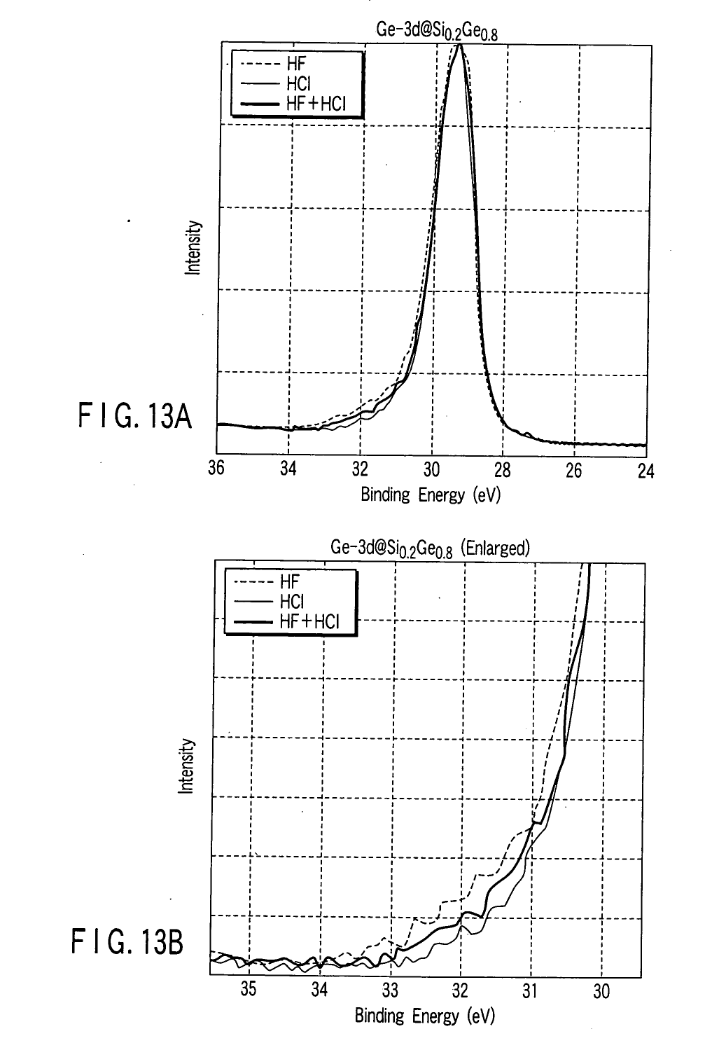

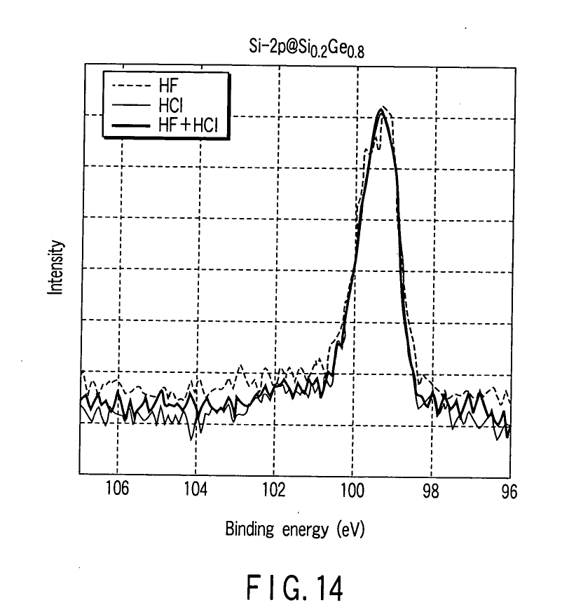

In the cleaning of the SGOI substrate surface, surface cleaning with hydrochloric acid alone having no hydrofluoric acid added thereto is effective in oxide removal. FIGS. 13A, 13B show XPS data (Ge-3d) after the SGOI substrate of Si 20% and Ge 80% is subjected to hydrofluoric acid cleaning (HF), hydrochloric acid cleaning (HCl), and hydrofluoric acid-added hydrochloric acid cleaning (HF+HCl), and FIG. 13B is an enlarged view of a portion around 32 eV of FIG. 13A. FIG. 14 shows XPS data (Si-2p) in the same cleaning.

It can be confirmed from FIGS. 13A, 13B that the cleaning with hydrochloric acid alone provides more effective oxide removal for Ge atoms as compared with the hydrofluoric acid cleaning, the hydrofluoric acid-added hydrochloric acid cleaning. It can be understood from FIG. 14 that a result of oxide removal of Si atoms is about equal. It has conventionally been known that a silicon oxide layer is formed on the surface when the Si substrate is dipped in the hydrochloric acid solution. However, it has been found that even when the surface of the SiGe substrate is processed with hydrochloric acid, Si of the SiGe surface of a high Ge composition (e.g., 50% or more) is never oxidized.

A hydrochloric acid concentration in this case is generally 20%. However, similar effects can be obtained even when the cleaning process is carried out at about 36% near an undiluted hydrochloric acid concentration, or even when it is carried out at a more diluted hydrochloric acid concentration of about 2%.

### Fifth Embodiment

Even when the layer to be grown after the cleaning is changed from the Ge layer to an SiGe layer in the first and second embodiments, a high-quality SiGe grown layer can be obtained by executing cleaning before growth similar to that of each of the first and second embodiments.

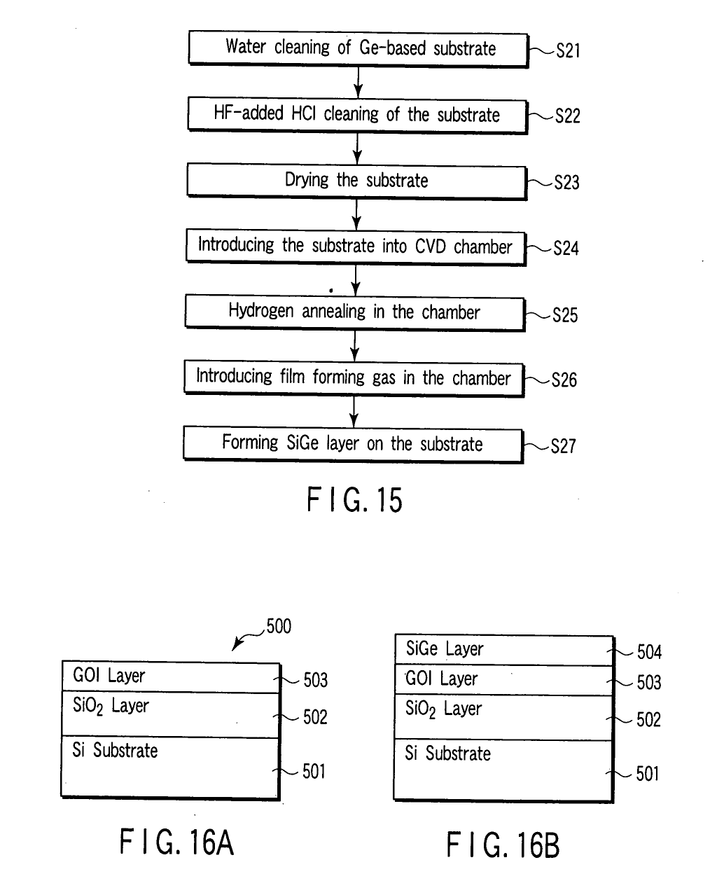

First, a GOI substrate 500 is prepared in which a GOI layer 503 is formed with a thickness of 20 nm through a silicon oxide layer 502 on a silicon substrate 501 (FIG. 16A). A surface of this GOI substrate 500 is first cleaned with pure water by a normal method (S21 of FIG. 15), and then cleaned with a hydrofluoric acid-added hydrochloric acid solution (S22). Hydrochloric acid in this case is generally dilute hydrochloric acid having a concentration of about 20%. However, similar effects can be obtained even when a cleaning process is carried out at about 36% near an undiluted hydrochloric acid concentration, or even when it is carried out at a more diluted hydrochloric acid concentration of about 2%. A concentration of hydrofluoric acid should be set to about 1 to 3%. The substrate after the dilute hydrochloric acid cleaning is immediately dried (S23).

Next, the cleaned and dried substrate is introduced into a CVD chamber (S24), and subjected to hydrogen annealing at, e.g., 450° C., 500 Pa for 5 minutes therein (S25). Subsequently, a deposition gas is introduced into the CVD chamber (S26), and an SiGe layer 504 is epitaxially grown at, e.g., 600° C., 1 Pa (S27). Accordingly, as shown in FIG. 16B, a high-quality flat SiGe layer 504 can be epitaxially grown as a channel layer on the GOI substrate 500.

According to the embodiment, the hydrochloric acid solution is used. However, similar effects can be obtained by using a hydrobromic acid (HBr) solution, a hydroiodic acid (HI) solution, or a solution prepared by adding hydrofluoric acid to such a solution in place of the hydrochloric acid solution.

### Sixth Embodiment

Even when the layer to be grown after the cleaning is changed from the Ge layer to an SiGe layer in the third and fourth embodiments, a high-quality SiGe grown layer can be obtained by executing cleaning before growth similar to that of each of the third and fourth embodiments.

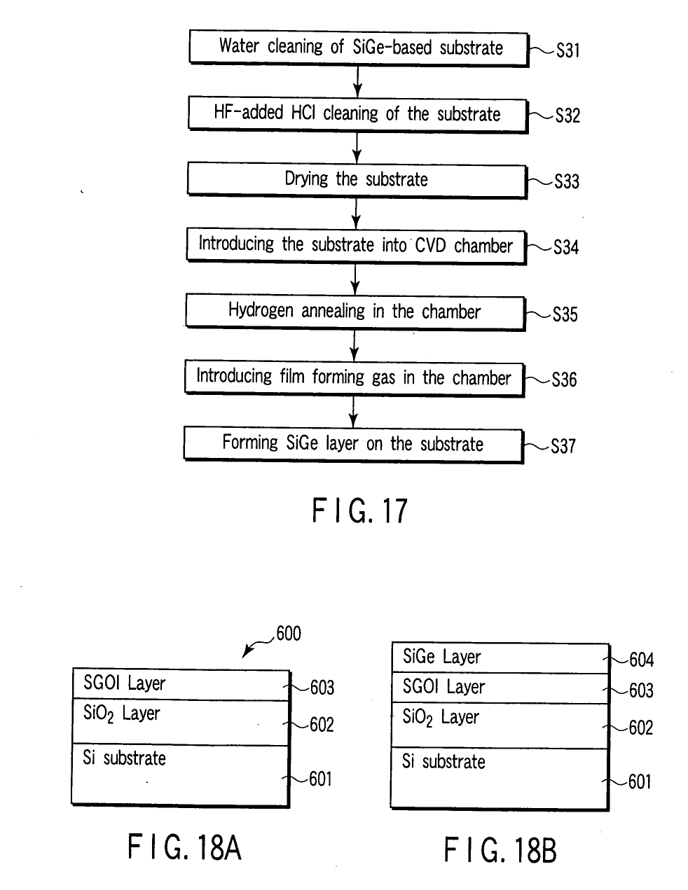

First, an SGOI substrate 600 is prepared in which an SGOI layer 603 is formed through a silicon oxide layer 602 on a silicon substrate 601 (FIG. 18A). A surface of this SGOI substrate 600 is first cleaned with pure water by a normal method (S31 of FIG. 17), and then cleaned with a hydrofluoric acid-added hydrochloric acid solution (S32). A concentration of hydrochloric acid in this case is generally about 20%. However, similar effects can be obtained even when a cleaning process is carried out at about 36% near an undiluted hydrochloric acid concentration, or even when it is carried out at a more diluted hydrochloric acid concentration of about 2%. A concentration of hydrofluoric acid should be set to about 1 to 3%. The substrate after the diluted hydrofluoric acid added hydrochloric acid cleaning is immediately dried (S33).

Next, the cleaned and dried substrate 600 is introduced into a CVD chamber (S34), and subjected to hydrogen annealing at, e.g., 800° C., 500 Pa for 20 minutes therein (S35). Subsequently, a deposition gas is introduced into the CVD chamber (S36), and an SiGe layer 604 is epitaxially grown at, e.g., 600° C., 1 Pa (S37). Accordingly, as shown in FIG. 18B, a high-quality flat SiGe layer 604 can be epitaxially grown as a channel layer on the SGOI substrate 600.

According to the embodiment, the hydrochloric acid solution is used. However, similar effects can also be obtained by using a hydrobromic acid (HBr) solution, a hydroiodic acid (HI) solution, or a solution prepared by adding hydrofluoric acid to such a solution in place of the hydrochloric acid solution.

### Seventh Embodiment

Even when the layer to be grown after the cleaning is changed from the Ge layer to an Si layer in the first and second embodiments, a high-quality Si layer can be obtained by executing cleaning before growth similar to that of each of the first and second embodiments.

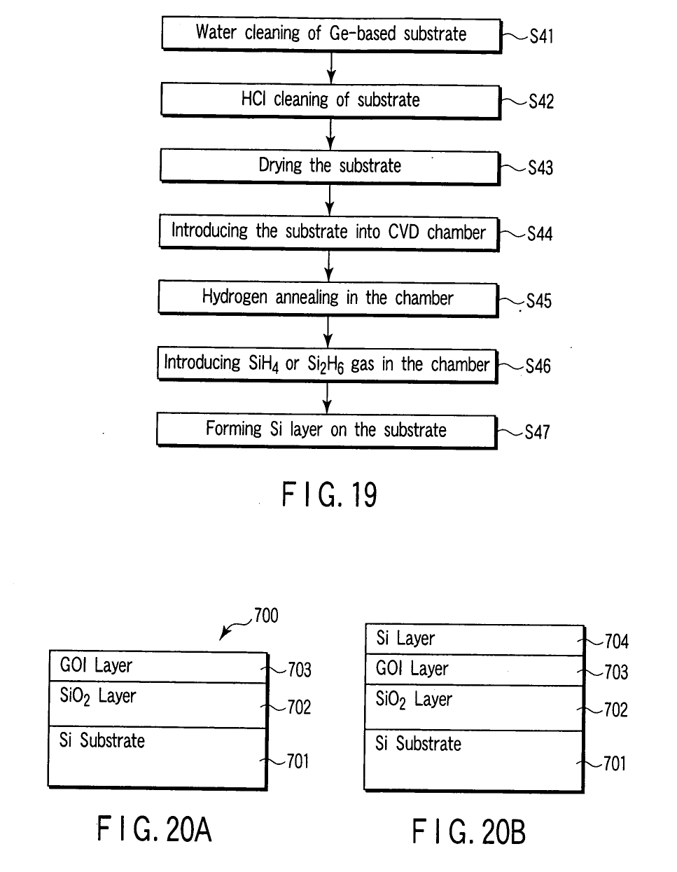

First, a GOI substrate 700 is prepared in which a GOI layer 703 is formed with a thickness of 20 nm through a silicon oxide layer 702 on a silicon substrate 701 (FIG. 20A). A surface of this GOI substrate 700 is first cleaned in pure water by a normal method (S41 of FIG. 19), and then cleaned with a hydrochloric acid solution (S42). Hydrochloric acid in this case is generally dilute hydrochloric acid having a concentration of about 20%. However, similar effects can be obtained even when a cleaning process is carried out at about 36% near an undiluted hydrochloric acid concentration, or even when it is carried out at a more diluted hydrochloric acid concentration of about 2%. The substrate after the dilute hydrochloric acid cleaning is immediately dried (S43).

Next, the cleaned and dried substrate 701 is introduced into a CVD chamber (S44), and subjected to hydrogen annealing at, e.g., 600° C., 500 Pa for 5 minutes therein (S45). Subsequently, a monosilane (SiH₄) gas is introduced into the CVD chamber (S46), and an Si layer 704 is epitaxially grown at, e.g., 500° C., 1 Pa (S47). Accordingly, as shown in FIG. 18B, a high-quality flat Si layer 704 can be epitaxially grown as a channel layer on the GOI substrate 700. Disilane (Si₂H₆) may be used in place of the monosilane.

According to the embodiment, the hydrochloric acid solution is used for the cleaning. However, similar effects can be obtained by using a hydrobromic acid (HBr) solution, a hydroiodic acid (HI) solution, or a solution prepared by adding hydrofluoric acid to such a solution in place of the hydrochloric acid solution.

The Si layer 704 can be used not only as the channel layer but also as a gate dielectric layer by being oxidized. By depositing a high-dielectric-constant layer (high-k layer) on the Si layer and subjecting it to heat treatment, a silicate layer can be formed to be used as a gate dielectric layer.

### Eighth Embodiment

Even when the layer to be grown after the cleaning is changed from the Ge layer to an Si layer in the third and fourth embodiments, a high-quality Si layer can be obtained by executing cleaning before growth similar to that of each of the third and fourth embodiments.

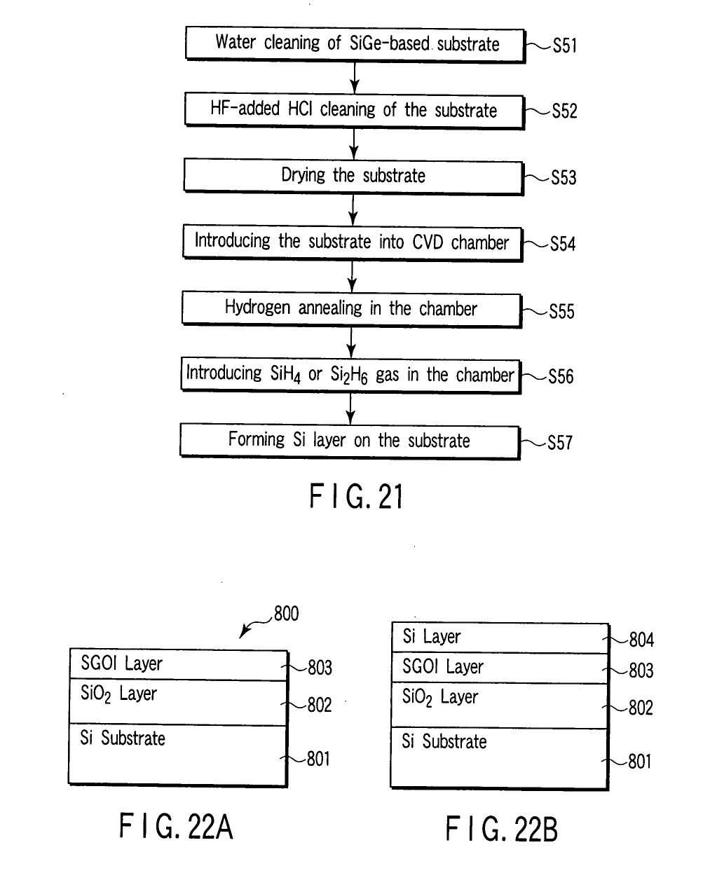

First, an SGOI substrate 800 is prepared in which an SGOI layer 803 is formed through a silicon oxide layer 802 on a silicon substrate 801 (FIG. 22A). A surface of this SGOI substrate 800 is first cleaned with pure water by a normal method (S51 of FIG. 21), and then cleaned with a hydrofluoric acid-added hydrochloric acid solution (S52). The concentration of hydrochloric acid in this case is generally about 20%. However, similar effects can be obtained even when a cleaning process is carried out at about 36% near an undiluted hydrochloric acid concentration, or even when it is carried out at a more diluted hydrochloric acid concentration of about 2%. The concentration of hydrofluoric acid should be set to about 1 to 3%. The substrate 800 after the diluted hydrofluoric acid added hydrochloric acid cleaning is immediately dried (S53).

Next, the cleaned and dried substrate 800 is introduced into a CVD chamber (S54), and subjected to hydrogen annealing at, e.g., 800° C., 500 Pa for 20 minutes therein (S55). Subsequently, a monosilane (SiH₄) gas is introduced into the CVD chamber (S56), and an Si layer 804 is epitaxially grown at, e.g., 600° C., 1 Pa (S57). Accordingly, as shown in FIG. 22B, a high-quality flat Si layer 804 can be epitaxially grown as a channel layer on the SGOI substrate 800. Disilane may be used in place of the monosilane.

According to the embodiment, the hydrochloric acid solution is used. However, similar effects can be obtained by using a hydrobromic acid (HBr) solution, a hydroiodic acid (HI) solution, or a solution prepared by adding hydrofluoric acid to such a solution in place of the hydrochloric acid solution.

As in the case of the seventh embodiment, the Si layer 804 can be used not only as the channel layer but also as a gate dielectric layer by being oxidized. By depositing a high-dielectric-constant layer on the Si layer and subjecting it to a heat treatment, a silicate layer can be formed to be used as a gate dielectric layer. A method of forming such a gate dielectric layer according to a ninth embodiment will be described below in detail.

### Ninth Embodiment

First, a method of converting the uppermost Si layer 704 into an insulting layer by using the laminated substrate of the seventh embodiment of FIG. 20B as a base will be described. A flat silicon layer 704 is formed with a thickness of 0.5 to 5 nm in the same process as that of the seventh embodiment, and this is converted into an insulating layer by the following method.

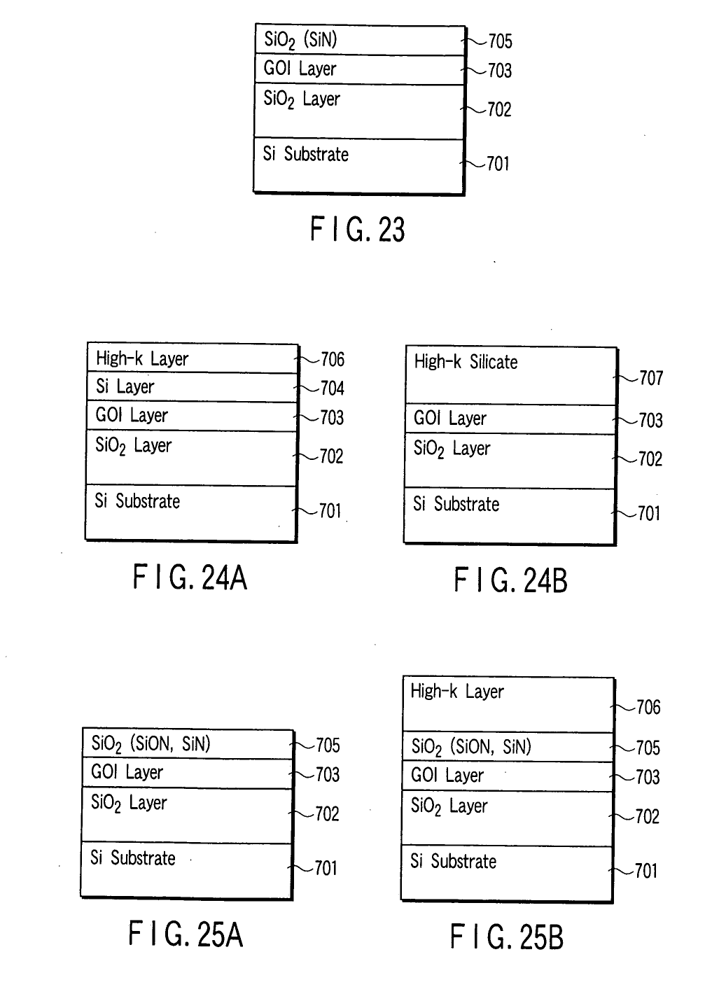

According to a first method, as shown in FIG. 23, the Si layer 704 is subjected to plasma oxidation (or radical oxidation) or plasma nitriding (or radical nitridation) to form a silicon oxide layer (alternatively silicon oxynitride layer, otherwise silicon nitride layer) 705. In this case, thermal oxidation or thermal nitridation may be used for the oxidizing or nitriding method.

According to a second method, a high-dielectric-constant layer (high-k layer) 706, having a dielectric constant higher than that of SiO₂, such as a hafnium (Hf) or zirconium (Zr) based silicon oxide layer is deposited on the silicon layer 704 by sputtering, atomic layer deposition (ALD) or the like (FIG. 24A), and then a heat treatment is carried out to form a silicate layer 707 (FIG. 24B).

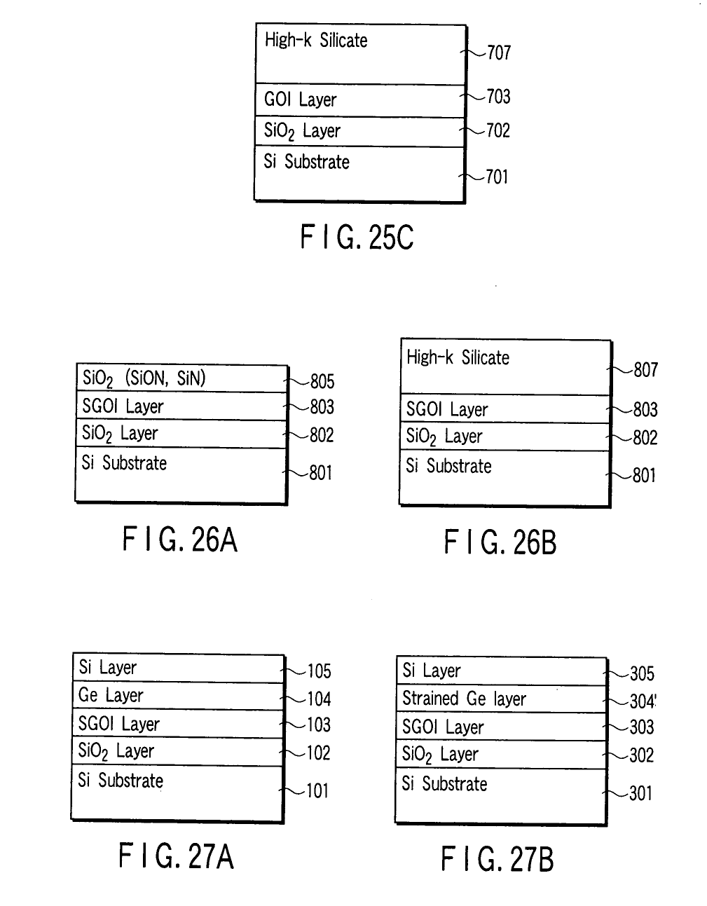

According to a third embodiment, as shown in FIG. 25A, the Si layer 704 is subjected to plasma oxidation (or radical oxidation) or plasma nitridation (or radical nitridation) to form a silicon oxide layer (alternatively silicon oxynitride layer, otherwise silicon nitride layer) 705. Then, a hafnium (Hf) or zirconium (Zr) based high-dielectric-constant layer 706 is deposited by sputtering, ALD or the like (FIG. 25B). Subsequently, a heat treatment is carried out to form a silicate layer 707 (FIG. 25C).

The GOI layer 703 and the silicate layer 707 thus formed constitute a good insulator/semiconductor interface. By using the laminated substrate of the eighth embodiment shown in FIG. 22B as a base, the uppermost Si layer 801 can be converted into an insulating layer 805 or a high-k silicate layer 807 by the three methods described above (FIGS. 26A, 26B).

Furthermore, a base may be configured as shown in FIG. 27A or 27B. FIG. 27A shows an Si layer 105 formed on the laminated structure of the first embodiment of FIG. 2B. FIG. 27B shows an Si layer 305 formed on the laminated structure of the third embodiment of FIG. 11B, and a Ge layer 304 converted into a strained Ge layer 304′. Therefore, it is possible to improve carrier mobility of the channel layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of forming a semiconductor layer, comprising:
cleaning a substrate having a germanium layer formed as a surface layer, with a solution containing at least one selected from the group consisting of hydrochloric acid, hydrobromic acid, and hydroiodic acid;
subjecting the substrate after said cleaning to hydrogen annealing in a CVD chamber; and
introducing a deposition gas into the CVD chamber to form a semiconductor layer on the substrate.

2. The method according to claim 1, wherein the substrate includes a base plate, an insulating layer formed on the base plate, and the germanium layer formed on the insulating layer.

3. The method according to claim 1, wherein the substrate is a germanium bulk substrate.

4. The method according to claim 1, wherein the solution further contains hydrofluoric acid.

5. The method according to claim 1, wherein the hydrogen annealing is performed at 500° C. or less.

6. The method according to claim 1, wherein the deposition gas includes a germane gas, and the semiconductor layer includes a germanium layer.

7. The method according to claim 1, wherein the deposition gas includes a monosilane or disilane gas, and a germane gas, and the semiconductor layer includes a silicon germanium layer.

8. The method according to claim 1, wherein the deposition gas includes a monosilane or disilane gas, and the semiconductor layer includes a silicon layer.

9. A method of forming a semiconductor layer, comprising:
cleaning a substrate having an SiGe layer formed as a surface layer, with a solution containing at least one selected from the group consisting of hydrochloric acid, hydrobromic acid, and hydroiodic acid;
subjecting the substrate after said cleaning to hydrogen annealing in a CVD chamber; and
introducing a deposition gas into the CVD chamber to form a semiconductor layer on the substrate.

10. The method according to claim 9, wherein the substrate includes a base plate, an insulating layer formed on the base plate, and a silicon germanium layer formed on the insulating layer.

11. The method according to claim 9, wherein the substrate includes a silicon substrate, and a silicon germanium layer crystal-grown on the silicon substrate.

12. The method according to claim 9, wherein the solution includes hydrofluoric acid.

13. The method according to claim 9, wherein the hydrogen annealing is performed at 850° C. or less.

14. The method according to claim 9, wherein the deposition gas includes a germane gas, and the semiconductor layer includes a germanium layer.

15. The method according to claim 9, wherein the deposition gas includes a monosilane or disilane gas, and a germane gas, and the semiconductor layer includes a silicon germanium layer.

16. The method according to claim 9, wherein the deposition gas includes a monosilane or disilane gas, and the semiconductor layer includes a silicon layer.

18. A method of forming a semiconductor layer, comprising:
cleaning a substrate having a germanium layer or a silicon germanium layer formed as a surface layer, with a solution containing at least one selected from the group consisting of hydrochloric acid, hydrobromic acid, and hydroiodic acid;
subjecting the cleaned substrate to hydrogen annealing in a CVD chamber;
introducing a monosilane or disilane gas into the CVD chamber to form a silicon layer on the substrate; and
insulating the silicon layer.

19. The method according to claim 18, wherein said insulating the silicon layer includes forming converting the silicon layer, the silicon layer into a silicon oxide layer or a silicon oxynitride layer.

20. The method according to claim 18, wherein said insulating the silicon layer includes forming a dielectric layer having a dielectric constant higher than that of a silicon oxide layer on the silicon layer, and applying a heat treatment to the silicon layer and the dielectric layer to form a silicate layer.

21. The method according to claim 18, wherein said insulating the silicon layer includes
converting the silicon layer into a silicon oxide or silicon oxide nitride layer,
forming a dielectric layer having a dielectric constant higher than that of the silicon oxide layer on the silicon oxide or silicon oxynitride layer, and
applying a heat treatment to the silicon oxide or silicon oxynitride layer and the dielectric layer.

22. The method according to claim 1, wherein the solution includes hydrofluoric acid.
